(19) United States
(12) Patent Application Publication
(10) Pub. No.: US 2025/0246456 A1
(43) Pub. Date: Jul. 31, 2025

(54) MULTI-STAGE EJECTOR AND METHOD FOR DRIVING THEREOF

(71) Applicant: FLC, Cheonan-si (KR)

(72) Inventors: Ganghyun MUN, Cheonan-si (KR); Sunghee CHO, Asan-si (KR)

(21) Appl. No.: 19/015,622

(22) Filed: Jan. 9, 2025

(30) Foreign Application Priority Data
Jan. 10, 2024 (KR) 10-2024-0004092

(51) Int. Cl. H01L 21/67

(52) U.S. Cl. CPC H01L 21/67132; H01L 21/67144

(57) ABSTRACT

Disclosed are a multi-stage ejector for separating a pickup-target chip from dicing tape in stages, and a method of driving the multi-stage ejector. The multi-stage ejector includes a plurality of ejecting blocks each including a contact portion that comes into contact with dicing tape, a lifting unit including a driving module configured to move the ejecting blocks upward or downward, and a restriction unit configured to limit a lifting height of each of the ejecting blocks. The ejecting blocks are configured such that the lifting height of an nth ejecting block is greater than the lifting height of an (n−1)th ejecting block positioned on a relatively outer side with respect to the nth ejecting block.

### CROSS-REFERENCE TO RELATED APPLICATION

This application claims priority to Korean Patent Application No. 10-2024-0004092, filed on Jan. 10, 2024, which is incorporated herein by reference in its entirety.

### BACKGROUND

### Technical Field

The present disclosure relates to a multi-stage ejector and a method for driving the multi-stage ejector, and more specifically, to a multi-stage ejector that separates a pickup-target chip from dicing tape in stages, and a method for driving the multi-stage ejector.

### Related Art

In a packaging process, which is a semiconductor back-end process, bonding refers to attaching a wafer chip to a substrate. One type of bonding, die bonding, involves attaching a semiconductor chip onto a lead frame or a printed circuit board (PCB) to establish an electrical connection of the semiconductor chip.

As shown in FIG. 1, in such die bonding, each semiconductor chip C that has undergone a dicing process exists in a state where the semiconductor chip C remains individually positioned and attached to dicing tape T. Typically, the semiconductor chip C is picked up using a plunger P and then placed onto a package substrate. Here, the semiconductor chip C, which is horizontally adhered to dicing tape T, is not easily separated due to adhesive. If excessive suction is applied, physical damage may occur to the semiconductor chip C. Therefore, a solution is needed to facilitate separation of the dicing tape T and the semiconductor chip C.

A structure that enables the separation of the semiconductor chip C is an ejector E. Generally, the ejector E applies pressure to a lower surface of the dicing tape T from beneath with an area smaller than that of the semiconductor chip C while simultaneously holding the dicing tape T by suction, thereby facilitating the separation of the dicing tape T from the semiconductor chip C, and assisting the pickup operation of the plunger P.

A conventional art related to such an ejector (hereinafter referred to as “conventional art”) is disclosed in Korean Patent No. 10-1931127. The conventional technology discloses a semiconductor manufacturing apparatus that includes a lift-up unit that pushes up a die from beneath dicing tape, and a collet that holds the die by suction. The lift-up unit includes a first unit having a plurality of rectangular blocks that contact the dicing tape, and a second unit having a plurality of concentric circular blocks each of which independently transmits up-and-down movement to a corresponding rectangular block. The semiconductor manufacturing apparatus allows the lift-up unit to be easily in modified according to the type of products.

However, the conventional technology requires a plurality of vertical driving units corresponding to the number of lift-up blocks (ejecting blocks), leading to excessive costs. Additionally, controlling the multiple lift-up blocks necessitates multi-axis motion position control technology. Therefore, there is a need for technology related to an ejector that has a simple operating structure and enables low-cost implementation.

### SUMMARY

The present disclosure has been devised to solve the above problem, and an object of the present disclosure is to provide a multi-stage ejector in which all ejecting blocks move upward for primary separation of an outer periphery of dicing tape, and the upward movement of each ejecting block is sequentially restricted from an outer side to a center, thereby achieving sequential separation of the dicing tape from the outer side to the center.

A multi-stage ejector according to an embodiment of the present disclosure may include: a plurality of ejecting blocks each including a contact portion that comes into contact with dicing tape; a lifting unit comprising a driving module configured to move the ejecting blocks upward or downward; and a restriction unit configured to limit a lifting height of each of the ejecting blocks. The plurality of ejecting blocks may be configured such that all of the ejecting blocks primarily move upward, and finally, the lifting height of an nth ejecting block is greater than the lifting height of an (n−1)th ejecting block positioned on a relatively outer side with respect to the nth ejecting block.

The lifting unit may further include a lifting block provided below one ejecting block positioned at an innermost side among the plurality of ejecting blocks (hereinafter referred to as a central ejecting block), and configured to move all of the ejecting blocks upward or downward. The driving module may include a first driving module configured to move the central ejecting block upward or downward, and a second driving module configured to move the lifting block upward or downward.

The lifting unit may further include an interlocking rod installed to penetrate sequentially from a first ejecting block positioned at an outermost side among the ejecting blocks, to the lifting block.

The restriction unit may include an upward movement restriction unit configured to limit the lifting heights of the ejecting blocks, and spacing restriction unit configured to limit a maximum spacing between the ejecting blocks.

The upward movement restriction unit may include an elastic element provided between the nth ejecting block and the (n−1)th ejecting block.

The elastic element may include a first elastic element provided between a first ejecting block that is an outermost ejecting block and a second ejecting block that is positioned at an inner side of the first ejecting block, and a second elastic element provided between the second ejecting block and a third ejecting block positioned at an inner side of the second ejecting block. An elastic force of the second elastic element may be greater than an elastic force of the first elastic element.

A difference in the elastic force between the first elastic element and the second elastic element may be determined by a compressed deformation length or a spring constant.

The spacing restriction unit may further include a bolt provided between the nth ejecting block and the (n−1)th ejecting block.

The bolt may include a head portion having a diameter larger than a diameter of a through-hole formed in the nth ejecting block, a body portion that is connected to the head portion and has a diameter smaller than or equal to that of the through-hole, and a threaded portion that is connected to the body portion and engaged with a threaded hole formed in the (n−1)th ejecting block.

When all of the ejecting blocks primarily move upward, a peripheral side portion of a chip may be separated from the dicing tape.

A method of driving a multi-stage ejector according to an embodiment of the present disclosure may include: operation S1 of moving upward all of a plurality of ejecting blocks each including a contact portion that comes into contact with dicing tape, and exposing the ejecting blocks outside an ejector hood; operation S2 of moving upward remaining blocks other than a first ejecting block disposed at an outermost side among the ejecting blocks; operation S3 of moving upward remaining blocks while sequentially excluding one block at a time, starting from a second ejecting block positioned immediately at an inner side of the first ejecting block; and operation S4 of moving upward only an nth block (hereinafter referred to as a central ejecting block) disposed at an innermost side among the ejecting blocks.

The method may further include operation S5 of moving downward all of the ejecting blocks and accommodating the ejecting blocks into the ejector hood after operation S4.

The upward movement of all of the ejecting blocks may be performed by moving upward a lifting block provided below the central ejecting block.

A driving module provided to move the ejecting blocks upward or downward may include a first driving module configured to move the central ejecting block upward or downward, and a second driving module configured to move the lifting block upward or downward.

Interlocked upward movement of the ejecting blocks and the lifting block may be performed by an interlocking rod that is installed to sequentially penetrate from the first ejecting block to the lifting block.

### BRIEF DESCRIPTION OF THE DRAWINGS

FIG. 1 is a diagram illustrating a concept of an ejector.

FIGS. 2 to 9 relate to embodiments of the present disclosure, and FIG. 2 is an exploded view of a multi-stage ejector according to the present disclosure.

FIG. 3 separately illustrates an ejecting block.

FIGS. 4 to 7 are cross-sectional views of the multi-stage ejector according to the present disclosure.

FIG. 8 is a diagram illustrating an operation sequence according to the present disclosure.

FIG. 9 is a diagram for describing a method of driving the multi-stage ejector.

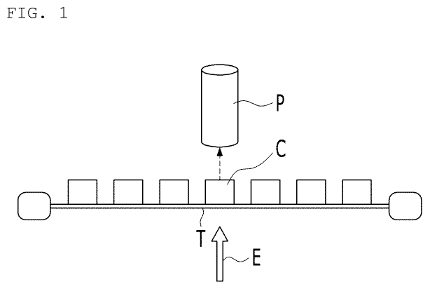

### DETAILED DESCRIPTION

While the present disclosure is susceptible to various modifications and alternative forms, embodiments (implantations) thereof will be described herein in detail. However, this is not intended to limit the present disclosure to particular modes of practice, and it should be understood that the present disclosure is to cover all modifications, equivalents, and alternatives falling within the spirit and scope of the present disclosure.

The terminology used herein is for the purpose of describing particular embodiments only and is not intended to be limiting the present disclosure. In the present disclosure, the singular forms are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms “first”, “second”, etc. are used only for the purpose for distinguishing a constitutive element from other constitutive elements, but the constitutive element should not be limited to a manufacturing order, and the terms described in the detailed description may not be consistent with those described in the claims.

Before providing a detailed description of the present disclosure, to avoid confusion in terminology, the terminology related to ejecting blocks is defined as follows: the expressions “disposed on an outer side” and “disposed on an inner side” are based on a portion (contact portion) of the ejecting block that is exposed to the outside of an ejector hood. From the perspective of a disc 11, an “ejecting block disposed on the outer side” refers to an “ejecting block disposed on an upper side,” whereas an “ejecting block disposed on the inner side” refers to an “ejecting block disposed on a lower side.” Since the difference in these expressions is based on the contact position relative to the component serving as the reference point, they should be interpreted according to the overall context of the sentence. Such definitions of terms are to be applied equally to the claims unless otherwise specified.

The present disclosure relates to a multi-stage ejector (hereinafter referred to as “the present apparatus”) and a driving method thereof (hereinafter referred to as “the present method”). The present apparatus includes a plurality of ejecting blocks, a lifting unit that moves the ejecting blocks upward or downward, and a restriction unit that limits the lifting height of each ejecting block. Furthermore, the present apparatus may further include a housing that accommodates components, including the ejecting blocks, and an ejector hood 4 that covers an open upper portion of the housing. The present apparatus allows the plurality of ejecting blocks to move upward simultaneously, to be exposed outside ejector hood 4. In this state, the ejecting blocks are sequentially restricted from further moving upward, starting with the ejecting block positioned at the outermost side, such that, in a final stage, only the ejecting block positioned at the innermost side continues to move upward, thus forming a mountain-like shape in which a central portion thereof is highest. The aforementioned configuration facilitates sequential separation of a pickup-target semiconductor chip from dicing tape T, starting from an outer side (outer periphery or peripheral side portion) thereof and progressing toward the center during a process of transferring the semiconductor chip by the plunger, thereby enabling easier separation of the semiconductor chip from the dicing tape T. Hereinafter, the present disclosure will be described in detail with reference to the accompanying drawings through embodiments of the present disclosure.

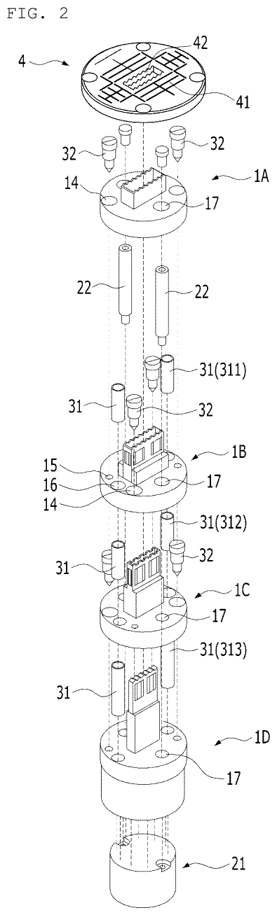

FIGS. 2 to 7 are diagrams illustrating embodiments of a multi-stage ejector according to the present disclosure. As shown in drawings, the present apparatus includes a plurality of ejecting blocks each having a contact portion that comes into contact with the dicing tape T. In the accompanying drawings, the number of ejecting blocks is limited to a total of four; however, it is assumed that the number of ejecting blocks may vary as needed.

In the present disclosure, the ejecting blocks are characterized in that the lifting height of an nth ejecting block is configured to be greater than the lifting height of a second ejecting block 1B, which is an (n−1)th block positioned relatively outward. In other words, the ejecting block at the exact center has the highest lifting height, while the ejecting block at the outermost side has the lowest lifting height, ensuring that dicing tape T is separated sequentially from the outer side toward the center.

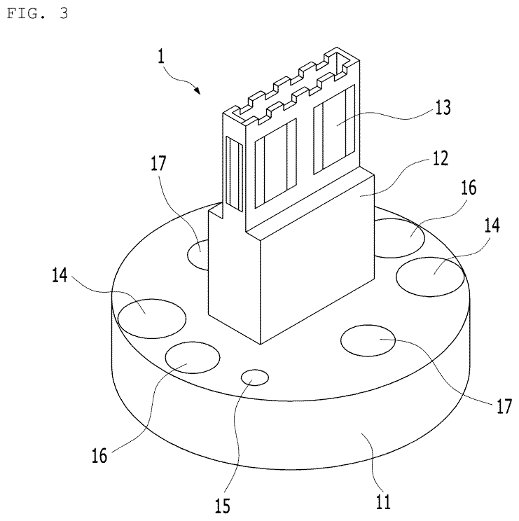

As a specific embodiment of the ejecting block, as illustrated in FIG. 3, each ejecting block 1 includes a disc 11, a column 12 formed vertically on the disc 11, a pusher 13 provided on an upper portion of the column 12, and a through-hole 14, a threaded hole 15, a mounting recess 16, and an interlocking hole 17 that are formed in the disc 11. The disc 11 has a hollow space therein.

Specifically, the disc 11 is a disc-shaped body that serves as a base of the ejecting block 1. The disc shape corresponds to an overall cylindrical shape of the present apparatus; however, it is not necessarily required to be formed in a disc shape. Although the disc 11 may have various forms, including polygonal or irregular shapes, it is preferable to have a somewhat standardized shape, such as a disc or a polygonal plate, to ensure the stability in upward or downward movement of the block.

The column 12 is configured to be vertically connected to the disc 11, and the length thereof is determined according to a height difference between the disc 11 and the ejector hood 4. Accordingly, the column 12 of an nth ejecting block that is positioned at the innermost side (for example, a fourth ejecting block 1D described later) is configured to be longer than the column 12 of a first ejecting block 1A positioned at the outermost side, thereby allowing the heights of the respective pushers 13 of the ejecting blocks 1 to be aligned at the same level in a standby state before being exposed above the ejector hood 4. Since the height of the pusher 13 of each ejecting block 1 may not necessarily be configured to be the same, each ejecting block 1 is ultimately configured such that the sum of the height of the column 12 and the height of the pusher 13 is the same.

The pusher 13 is configured to contact the dicing tape T and push up the dicing tape T, with an upper surface of the pusher 13 serving as a contact portion that comes into contact with the dicing tape T. The column 12 and the pusher 13 may be configured in a rectangular pillar shape according to the shape of the dicing tape T but are not necessarily limited thereto. The pusher 13 may have a smaller cross-sectional area than the column 12 such that a step is formed between the column 12 and the pusher 13. In addition, the contact portion, which is the upper surface of the pusher 13, may have a concave-convex structure in which protrusions and recesses are alternately arranged. The concave-convex structure maintains pressing efficiency on the dicing tape T while allowing the pusher 13 to easily detach from a lower surface of the dicing tape T when the pressing force is released.

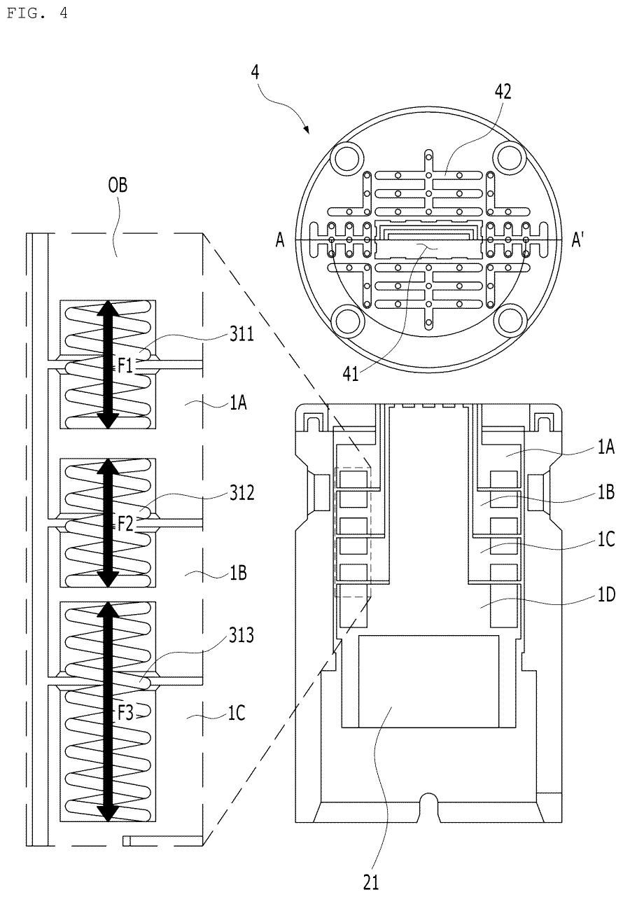

As shown in FIGS. 4 to 7, each of the disc 11, the column 12, and the pusher 13 has a hollow space therein, allowing the column 12 and the pusher 13 of an nth ejecting block (for example, a third ejecting block 1C described later) positioned relatively inward to be received in the hollow space of an (n−1)th ejecting block (for example, the second ejecting block 1B described later) positioned relatively outward. Through the aforementioned configuration, the ejecting blocks are stacked in an overlapping manner, and are stacked with a predetermined gap formed therebetween by an elastic element 31 described later.

It is apparent that the hollow space of each ejecting block may be formed in a shape corresponding to the shape of the column 12 and the pusher 13 of the overlapping (n−1)th ejecting block.

The through-hole 14 is formed in the disc 11 and is configured to allow a bolt 32, which connects two adjacent ejecting blocks, to pass through. The through-hole 14 may be a hole formed throughout the entire disc 11 along a vertical direction.

The threaded hole 15 is formed in the disc 11 and is configured such that the bolt 32 passing through the through-hole 14 is tightened into the threaded hole 15. The threaded hole 15 has a thread corresponding to that of the bolt 32 and may be a hole formed partially or entirely along the vertical direction of the disc 11. The threaded hole 15 may not be formed in the disc 11 of the first ejecting block 1A, which is disposed at an uppermost position.

In addition, the mounting recess 16 is configured to receive the elastic element 31 that limits upward movement of the corresponding ejecting block by restricting the spacing between two adjacent ejecting blocks to a certain length or less. The mounting recess 16 is formed not only in an upper surface but also in a lower surface of the disc 11 and may be a recess formed partially along the vertical direction of the disc 11. The mounting recess 16 may not be formed in the lower surface of the disc 11 of the central ejecting block that is disposed at a lowermost position (the fourth ejecting block 1D described later).

The interlocking hole 17 is configured to allow an interlocking rod 22, described later, to pass through and is formed in the disc 11. The interlocking hole 17 may be a hole formed entirely along the vertical direction of the disc 11. The interlocking hole 17 is formed throughout, from the disc 11 of the first ejecting block 1A, which is disposed at the uppermost position, to a lifting block 21, which is disposed at the lowermost position. Accordingly, upward or downward movement of all of the ejecting blocks may be interlocked with upward or downward movement of the lifting block 21.

Next, as illustrated in FIGS. 2 to 7, the present apparatus may further include a lifting unit for implementing the upward or downward movement of the ejecting blocks. The lifting unit may include a driving module that moves the ejecting blocks upward or downward. The driving module may broadly include a configuration that physically moves the ejecting blocks upward or downward and a configuration that provides power. The configuration that physically moves the ejecting blocks upward or downward may be a configuration that directly contacts and pushes up the blocks, such as a piston rod or a pushing plate. The configuration that provides power may employ various structures, such as a hydraulic cylinder system, a pneumatic cylinder system, or a motor-driven system, and the present disclosure does not particularly limit the type thereof.

As shown in FIGS. 2 to 7, the lifting unit may further include a lifting block 21, which is provided below the central ejecting block (the fourth ejecting block 1D in FIG. 2) that is disposed at the innermost position among the ejecting blocks, to move all of the ejecting blocks upward or downward. More specifically, as shown in FIG. 2, the lifting block 21 has a shape similar to the disc 11 of the ejecting block and has a shape corresponding to the hollow space of the central ejecting block so that the lifting block 21 can be inserted into the hollow space of the central ejecting block. In the illustrated embodiment, the lifting block 21 has a cylindrical shape. The lifting block 21 moves upward or downward by a second driving module, described later, and pushes up all of the ejecting blocks, including the central ejecting block, during upward movement.

The driving module may include a second driving module that moves the lifting block 21 upward or downward, and a first driving module that moves the central ejecting block upward or downward. The second driving module is provided below the lifting block 21 to move the lifting block 21 upward, thereby causing upward movement of all of the ejecting blocks, including the lifting block 21. Furthermore, the first driving module moves upward the central ejecting block, which is the ejecting block disposed at the innermost position, thereby causing upward movement of each of the ejecting blocks. In other words, when the second driving module moves the lifting block 21 upward, all of the ejecting blocks move upward together. When the first driving module moves the central ejecting block CB upward, each of the ejecting blocks sequentially moves upward due to a restriction unit, described later.

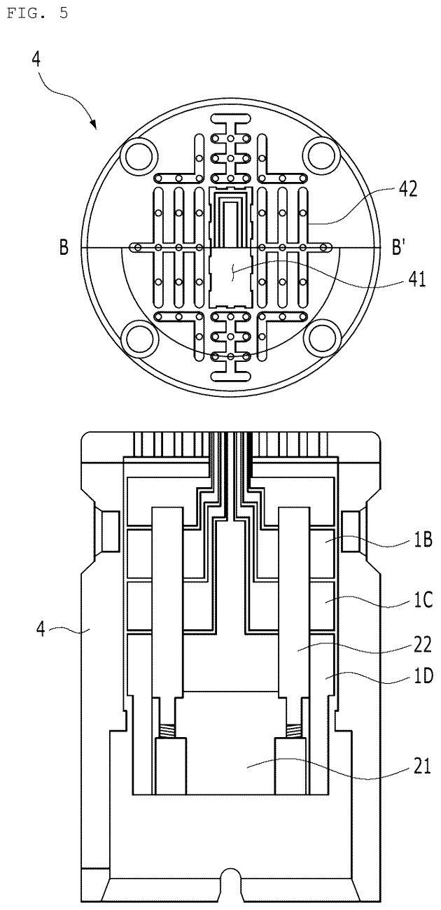

In addition, as shown in FIGS. 2 and 5, the lifting unit may further include the interlocking rod 22, which is installed to penetrate sequentially from the first ejecting block 1A, positioned at an outermost side among the ejecting blocks, to the lifting block 21. As described above, all of the ejecting blocks have the respective interlocking holes 17 through which the interlocking rod 22 passes. The interlocking rod 22 is installed to penetrate all of the interlocking holes 17, extending from the uppermost first ejecting block 1A to the lowermost lifting block 21. Accordingly, when the lifting block 21 moves upward, all of the ejecting blocks, which are interlocked and coupled by the interlocking rod 22, simultaneously move upward. The interlocking rod 22 also ensures linear movement of each of the ejecting blocks during the upward or downward movement, thereby contributing to a reliable upward or downward movement operation.

In the present disclosure, all of the ejecting blocks are primarily moved upward as a whole by the first driving module so that all of the ejecting blocks are exposed outside an exposed portion 42 of the ejector hood 4. In this state, the second driving module restricts upward movement of each ejecting block sequentially from the outer side, thereby forming stepwise upward movement with a convex central portion, facilitating the separation of the dicing tape T. The following restriction unit corresponds to an essential component for implementing the stepwise upward movement.

The present disclosure, compared to a structure equipped with a single vertical driving unit, primarily enables separation of the outer periphery of the dicing tape T first, followed by the separation of the dicing tape to the central portion in stages, thereby allowing more reliable and easier separation of the dicing tape T. Furthermore, because only two vertical driving units are provided, the present disclosure may not only reduce costs compared to providing a vertical driving unit for each ejecting block but may also simplify a control algorithm of the vertical driving units.

Next, as illustrated in FIGS. 2 to 7, the present apparatus may further include a restriction unit configured to limit the lifting height of each of the ejecting blocks.

The restriction unit may include an upward movement restriction unit that limits the lifting height of each of the ejecting blocks, and a spacing restriction unit that limits the spacing between the ejecting blocks. The upward movement restriction unit limits the lifting height of each of the ejecting blocks during upward movement, preventing the ejecting block from moving upward beyond a certain height, thereby implementing the stepwise upward movement of the ejecting blocks, which is the key feature of the present disclosure. Furthermore, the spacing restriction unit limits the maximum spacing between the ejecting blocks, ensuring that during downward movement of the ejecting blocks, the spacing between each pair of ejecting blocks does not exceed a certain distance, thereby allowing all of the ejecting blocks to move downward in an interlocked manner.

As a specific embodiment of the upward movement restriction unit, as illustrated in FIGS. 2 and 4, the upward movement restriction unit may include the elastic element 31 provided between the nth ejecting block and the (n−1)th ejecting block. In a more specific embodiment, the elastic element 31 may be a spring. Here, it is assumed that the concepts of “first” and “second” refer to relative positions, as in the nth and (n−1)th ejecting blocks, and do not designate a specific ejecting block among the multiple ejecting blocks. The elastic element 31 is compressed during the upward movement of the ejecting block, providing resistance to the lifting force generated by the driving module, thereby restricting the upward movement of the ejecting block.

Furthermore, to implement the stepwise upward movement operation of the present disclosure as described above, the ejecting blocks may include the first ejecting block 1A, the second ejecting block 1B disposed at an inner side of the first ejecting block 1A, the third ejecting block 1C disposed at an inner side of the second ejecting block 1B, and the fourth ejecting block 1D disposed at an inner side of the third ejecting block 1C, as illustrated in FIG. 4.

The elastic element 31 may include a first elastic element 311 provided between the first ejecting block 1A and the second ejecting block 1B, a second elastic element 312 provided between the second ejecting block 1B and the third ejecting block 1C, and a third elastic element 313 provided between the third ejecting block 1C and the fourth ejecting block 1D.

Here, an elastic force of the second elastic element 312 may be configured to be greater than that of the first elastic element 311, and an elastic force of the third elastic element 313 may be configured to be greater than that of the second elastic element 312.

Accordingly, when a pressure is applied such that the first elastic element 311 is fully compressed while the second elastic element 312 is not fully compressed, the complete compression of the first elastic element 311 causes the first ejecting block 1A and the second ejecting block 1B to come into contact with each other, preventing further upward movement of the second ejecting block 1B. When a pressure sufficient to fully compress the second elastic element 312 in addition to the first elastic element 311 is applied due to the upward movement by the first driving module, the complete compression of the second elastic element 312 causes the second ejecting block 1B and the third ejecting block 1C to come into contact with each other, thereby preventing further upward movement of the third ejecting block 1C. That is, the more inwardly positioned the ejecting block is, the stronger the elastic element 31 restricting the upward movement of the ejecting block is configured to be. Through the aforementioned arrangement, the upward movement of the ejecting blocks is sequentially restricted from the outer side to the inner side, ultimately allowing only the central ejecting block to move upward. As a result, when viewed from the side, the ejecting blocks form a stepped structure having a mountain-like shape with a convex center. FIG. 4 shows that the elastic forces of the first to third elastic elements 311 to 313, which restrict the upward movement of the four ejecting blocks, increase in reverse order.

As an embodiment related to the elastic element 31, a difference in elastic force between the first elastic element 311 and the second elastic element 312 may be determined by a compressed deformation length or a spring constant. Generally, factors determining the magnitude of the elastic force of the elastic element 31 include the spring constant, which is influenced by the material of the elastic element 31, a coil diameter of the elastic element 31, and an outer diameter of the elastic element 31, and the compressed deformation length of the spring. In the present embodiment, to reduce manufacturing costs associated with spring production and to precisely control the elastic force, the spring constant is selected to be the same, and only the compression length of the spring is used to adjust the elastic force.

As a specific embodiment of the spacing restriction unit, as illustrated in FIGS. 2 and 5 to 7, the spacing restriction unit may include the bolt 32 provided between the nth ejecting block and the (n−1)th ejecting block.

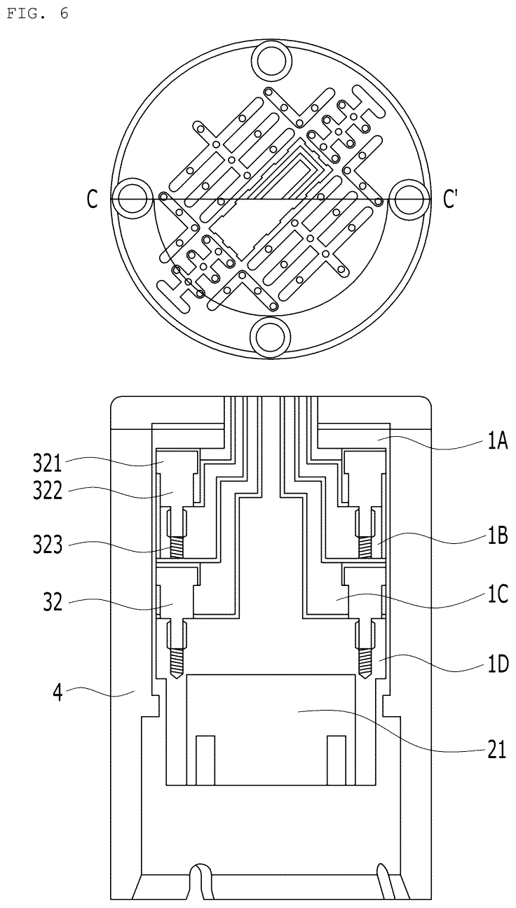

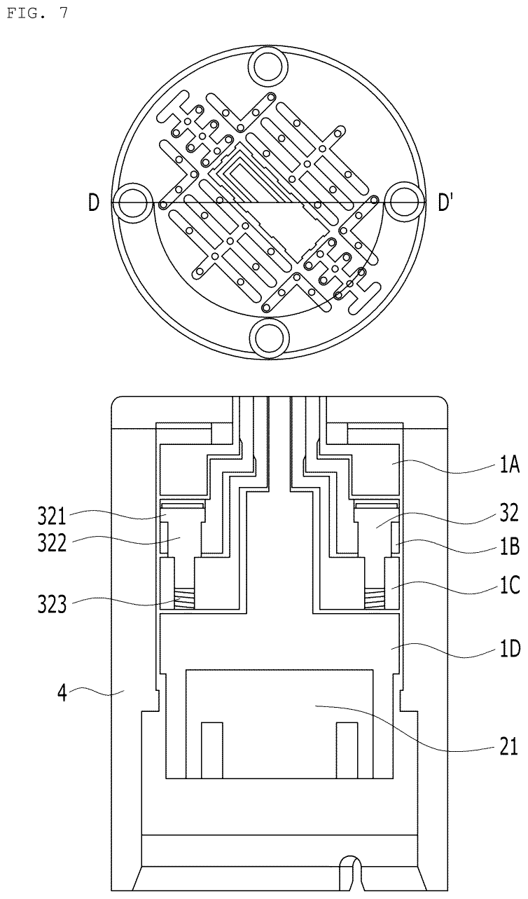

Referring to FIGS. 6 and 7, the bolt 32 may include a head portion 321 having a diameter larger than that of the through-hole 14 formed in the (n−1)th ejecting block, a body portion 322 that is connected to the head portion 321 and has a diameter smaller than or equal to that of the through-hole 14, and a threaded portion 323 that is connected to the body portion 322 and engaged into the threaded hole 15 formed in the nth ejecting block. The body portion 332 serves as a non-threaded section formed without thread formation, and as a result, the spacing between the ejecting blocks is adjusted according to the length of the body portion 332. In the case where the spacing restriction unit is implemented using the bolt 32 as described above, when the nth ejecting block moves upward and comes into contact with the (n−1)th ejecting block, the height of the bolt 32 relative to the (n−1)th ejecting block also increases, causing the (n−1)th ejecting block to be positioned closer to the threaded portion 323. In this state, when the nth ejecting block moves downward, the head portion 321 of the bolt 32 is engaged with a portion defining the through-hole 14 in the (n−1)th ejecting block, thereby interlocking the downward movement of the nth ejecting block and the (n−1)th ejecting block. The state in which the portion defining the through-hole 14 and the head portion 321 are in contact defines the maximum spacing between the nth ejecting block and the (n−1)th ejecting block, preventing further separation.

The present apparatus may further include a housing that accommodates the components, including the ejecting blocks, and the ejector hood 4 that covers an open upper portion of the housing. In FIG. 2, an upper plate of the ejector hood 4 is illustrated. The ejector hood 4 may include, in an upper surface thereof, a suction port 41 provided to secure a lower surface of the dicing tape T by suction and an exposed portion 42 provided at the center to allow the ejecting blocks to be exposed. In the attached drawings, an embodiment is illustrated in which the exposed portion 42 is configured in a rectangular shape, and the suction port 41 is configured as holes arranged uniformly around the exposed portion 42. However, it is assumed that the configuration is not necessarily limited to the aforementioned shape.

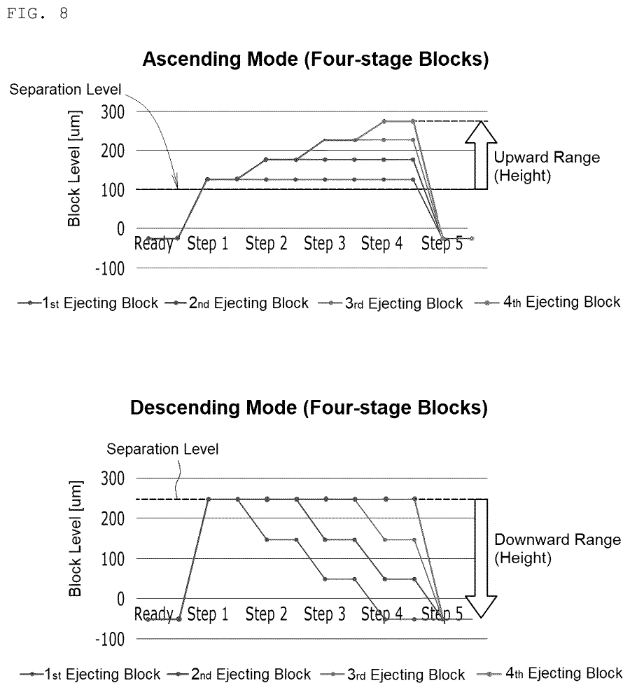

FIG. 8 is a diagram for explaining an operation process of the present apparatus. As illustrated in FIG. 8, when a first step (Step 1) is reached in a preparation stage, all of the ejecting blocks move upward, and the height of the contact portion becomes equal to or greater than an outer peripheral separation level. In other words, all of the ejecting blocks protrude above the exposed portion 42 of the ejector hood 4. Here, as illustrated in the lower diagram of FIG. 8, both the second driving module, which moves all of the ejecting blocks upward or downward, and the first driving module, which sequentially moves upward each of the ejecting blocks, move upward. Here, the upward movement of the first driving module may be dependent on the second driving module or may be performed independently.

Thereafter, when a second step (Step 2) is reached, the remaining ejecting blocks other than the outermost ejecting block move upward. After passing through a third step (Step 3), only the central ejecting block moves upward in a fourth step (Step 4). In this state, as illustrated in the lower diagram of FIG. 8, the second driving module stops the upward movement, and only the first driving module, which sequentially moves each of the ejecting blocks upward, moves upward.

Thereafter, once the pickup of the semiconductor chip is completed, the process enters a fifth step (Step 5), in which all of the ejecting blocks move downward so that the heights of the contact portions become equal to or lower than the outer peripheral separation level. That is, all of the ejecting blocks are retracted into the ejector hood 4. In this state, as illustrated in the lower diagram of FIG. 8, both the first driving module and the second driving module move downward. In addition, by applying the above sequence in reverse, a stepwise downward movement operation can also be implemented, in which all of the ejecting blocks that have moved upward to the outer peripheral separation level move downward sequentially from the first ejecting block 1A to the central ejecting block. Therefore, the present disclosure should not be construed as being limited to the stepwise upward movement operation but may also be applied to the stepwise downward movement operation.

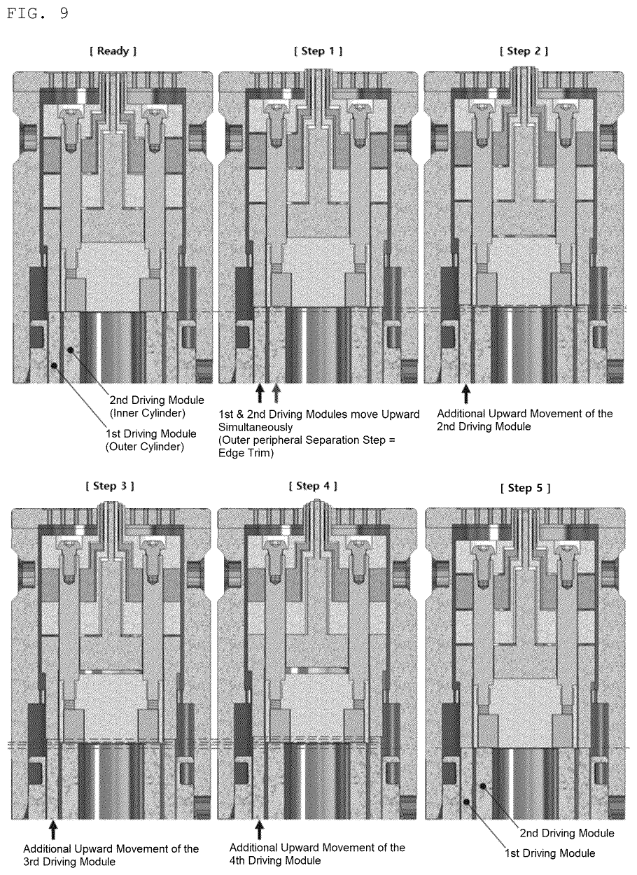

FIG. 9 is a diagram for describing a method (present method) of driving the multi-stage ejector according to the present disclosure. The present method will be described with reference to FIG. 9. Before providing a detailed description, the mechanical configurations for implementing the present method are to be substituted with the above-described explanation of the present apparatus.

The present method may include step S1 of moving upward all of the ejecting blocks, each including the contact portion that comes into contact with the dicing tape T, and exposing the ejecting blocks outside the ejector hood 4. In step S1, the outer peripheral separation of the dicing tape T is performed, and the range of separation corresponds to the sum of areas of the contact portions of the ejecting blocks. As mentioned above, both the second driving module, which moves upward all of the ejecting blocks, and the first driving module, which sequentially moves upward each of the ejecting blocks, move upward. The second driving module moves upward the lifting block 21, while the first driving module moves upward the central ejecting block. Here, the pressing force of the first driving module may not necessarily be applied.

As described above, the upward movement of all of the ejecting blocks may be achieved by the upward movement of the lifting block 21, which is provided below the central ejecting block. The interlocked upward movement of the ejecting blocks and the lifting block 21 may be achieved by an interlocking rod 22, which is installed to penetrate sequentially from the first ejecting block 1A to the lifting block 21.

Next, the present method may further include step S2 of moving upward the remaining ejecting blocks other than the first ejecting block 1A disposed at the outermost side among the ejecting blocks. Referring to FIG. 9, in the second step (Step 2), it can be confirmed that blocks 2, 3, and 4 move upward, excluding block 1, which is the first ejecting block 1A positioned at the outermost side. Here, block 1 moves upward by a simultaneous upward movement distance of a, and blocks 2, 3, and 4 move upward by a distance of a+b. By step S2, separation occurs in the portion of the dicing tape T that has been in contact with block 1.

Next, the present method may further include step S3 of moving upward the remaining blocks while sequentially excluding one block at a time, starting from the second ejecting block 1B positioned immediately at an inner side of the first ejecting block 1A. Referring to FIG. 9, in the third step (Step 3), it can be confirmed that blocks 3 and 4 move upward, excluding block 2, which is the second ejecting block 1B. Here, block 2 moves upward by a+b, and blocks 3 and 4 move upward by a+b+c. By step S3, additional separation occurs in the portion of the dicing tape T that has been in contact with block 2.

Next, the present method may further include step S4 of moving upward only the central ejecting block, which is positioned at the innermost side among the ejecting blocks. Referring to FIG. 9, in the fourth step (Step 4), it can be confirmed that only block 4, which is the central ejecting block, moves upward. Here, block 3 moves upward by a+b+c, and block 4 moves upward by a+b+c+d. By step S4, additional separation occurs in the portion of the dicing tape T that has been in contact with block 3. Since an adhesion range between the pickup-target chip and the dicing tape T is reduced to the contact portion area of block 4, which is the central ejecting block, the pickup operation using the plunger can be performed more easily.

Next, the present method may further include step S5 downward all of the ejecting blocks and of moving accommodating the ejecting blocks into the ejector hood 4 after step S4 corresponding to the final upward movement sequence. Referring to FIG. 9, in the fifth step (Step 5), it can be confirmed that all of the ejecting blocks move downward and return to the standby position (inside the ejector hood 4). Each of the blocks moves downward by the same distance as the upwardly moved distance of the block, thereby returning to the same height.

The present disclosure, having the above-described configuration, steps, and features, primarily separates an outer periphery of dicing tape and then separates the dicing tape toward a center in stages, thereby enabling a more reliable and easier separation of the dicing tape.

Furthermore, because only two vertical driving units are provided, the present disclosure has the effects of not only reducing costs compared to providing a vertical driving unit for each ejecting block but also simplifying a control algorithm of the vertical driving units.

In addition, since driving positions of the two vertical driving units are configured to be motion-controllable, the present disclosure has the effects of precisely adjusting the height of all of the ejecting blocks, where outer peripheral separation occurs, and selectively performing either a stepwise upward movement operation or a stepwise downward movement operation, depending on a control sequence of the two vertical driving units.

The present disclosure described above with reference to the accompanying drawings may be variously modified and changed by those of ordinary skill in the art, and such modifications and changes that are not limited by the claims should be construed as being included in the scope of the present disclosure.

What is claimed is:

1. A multi-stage ejector comprising:
a plurality of ejecting blocks each including a contact portion that comes into contact with dicing tape; a lifting unit comprising a driving module configured to move the ejecting blocks upward or downward; and a restriction unit configured to limit a lifting height of each of the ejecting blocks,
wherein the plurality of ejecting blocks are configured such that all of the ejecting blocks primarily move upward, and finally, the lifting height of an nth ejecting block is greater than the lifting height of an (n−1)th ejecting block positioned on a relatively outer side with respect to the nth ejecting block.

2. The multi-stage ejector of claim 1,
wherein the lifting unit further comprises a lifting block provided below one ejecting block positioned at an innermost side among the plurality of ejecting blocks (hereinafter referred to as a central ejecting block), and configured to move all of the ejecting blocks upward or downward, and
wherein the driving module comprises a first driving module configured to move the central ejecting block upward or downward, and a second driving module configured to move the lifting block upward or downward.

3. The multi-stage ejector of claim 2, wherein the lifting unit further comprises an interlocking rod installed to penetrate sequentially from a first ejecting block positioned at an outermost side among the ejecting blocks, to the lifting block.

4. The multi-stage ejector of claim 1, wherein the restriction unit includes an upward movement restriction unit configured to limit the lifting heights of the ejecting blocks, and a spacing restriction unit configured to limit a maximum spacing between the ejecting blocks.

5. The multi-stage ejector of claim 4, wherein the upward movement restriction unit comprises an elastic element provided between the nth ejecting block and the (n−1)th ejecting block.

6. The multi-stage ejector of claim 5,
wherein the elastic element comprises a first elastic element provided between a first ejecting block that is an outermost ejecting block and a second ejecting block that is positioned at an inner side of the first ejecting block, and a second elastic element provided between the second ejecting block and a third ejecting block positioned at an inner side of the second ejecting block, and
wherein an elastic force of the second elastic element is greater than an elastic force of the first elastic element.

7. The multi-stage ejector of claim 6, wherein a difference in the elastic force between the first elastic element and the second elastic element is determined by a compressed deformation length or a spring constant.

8. The multi-stage ejector of claim 4, wherein the spacing restriction unit further comprises a bolt provided between the nth ejecting block and the (n−1)th ejecting block.

9. The multi-stage ejector of claim 8, wherein the bolt comprises a head portion having a diameter larger than a diameter of a through-hole formed in the nth ejecting block, a body portion that is connected to the head portion and has a diameter smaller than or equal to that of the through-hole, and a threaded portion that is connected to the body portion and engaged with a threaded hole formed in the (n−1)th ejecting block.

10. The multi-stage ejector of claim 1, wherein when all of the ejecting blocks primarily move upward, a peripheral side portion of a chip is separated from the dicing tape.

11. A method of driving a multi-stage ejector, the method comprising:
operation S1 of moving upward all of a plurality of ejecting blocks each including a contact portion that comes into contact with dicing tape, and exposing the ejecting blocks outside an ejector hood;
operation S2 of moving upward remaining blocks other than a first ejecting block disposed at an outermost side among the ejecting blocks;
operation S3 of moving upward remaining blocks while sequentially excluding one block at a time, starting from a second ejecting block positioned immediately at an inner side of the first ejecting block; and
operation S4 of moving upward only an nth block (hereinafter referred to as a central ejecting block) disposed at an innermost side among the ejecting blocks.

12. The method of claim 11, further comprising operation S5 of moving downward all of the ejecting blocks and accommodating the ejecting blocks into the ejector hood after operation S4.

13. The method of claim 11, wherein the upward movement of all of the ejecting blocks is performed by moving upward a lifting block provided below the central ejecting block.

14. The method of claim 13, wherein a driving module provided to move the ejecting blocks upward or downward comprises a first driving module configured to move the central ejecting block upward or downward, and a second driving module configured to move the lifting block upward or downward.

15. The method of claim 13, wherein interlocked upward movement of the ejecting blocks and the lifting block is performed by an interlocking rod that is installed to sequentially penetrate from the first ejecting block to the lifting block.
